(19) United States
(12) Patent Application Publication
(10) Pub. No.: US 2006/0002308 A1
(43) Pub. Date: Jan. 5, 2006

(54) Apparatus and method for managing information in multimedia service providing system

(75) Inventors: Ho-Taek Na, Yongin-si (KR); Jae-Man Kim, Suwon-si (KR)

Correspondence Address: ROYLANCE, ABRAMS, BERDO & GOODMAN, L.L.P., 1300 19TH STREET, N.W., SUITE 600, WASHINGTON,, DC, 20036, US

(73) Assignee: Samsung Electronics Co., Ltd.

(21) Appl. No.: 11/168,564

(22) Filed: Jun. 29, 2005

(30) Foreign Application Priority Data
Jun. 30, 2004 (KR) 2004-50919

(51) Int. Cl. G01R 31/08

(52) U.S. Cl. 370/252

(57) ABSTRACT

An apparatus and method for managing information in an integrated service providing system are provided. An exemplary integrated service providing system performing the steps to manage information by receiving a service request message from the terminal, transmitting a domain name server (DNS) inquiry message including the ID information of the terminal to a server that manages the unique information of a subscriber information management server, receiving, from the server, a DNS response message that includes the unique information of the subscriber information management server corresponding to the ID of the terminal and obtaining the subscriber information of the terminal from the subscriber information management server according to the received unique information of the subscriber information management server.

### CLAIM OF PRIORITY

This application claims the benefit under 35 U.S.C. § 119(a) of Korean Patent Application No. 2004-50919 filed in the Korean Intellectual Property Office on Jun. 30, 2004, the entire disclosure of which is hereby incorporated by reference.

### BACKGROUND OF THE INVENTION

1. Field of the Invention

The present invention relates to an apparatus and method for managing information in an integrated service providing system. More particularly, the present invention relates to an apparatus and method for managing information in an integrated service providing system, which is capable of efficiently performing a subscription locator function (SLF) to confirm unique information of a home subscriber server (HSS), which manages information regarding a terminal subscriber upon receipt of a message from a terminal by implementing a number of HSSs as the number of subscribers accessing an IP multimedia core network subsystem (IMS) on an ALL-IP network increases.

2. Description of the Related Art

The European 3GPP and North American 3GPP2, promoting IMT-2000 standards, have suggested an ALL-IP network in which IP is substituted for a mobile communication network infrastructure.

The ALL-IP network is expected to meet an increasing variety of Internet users' service requests by providing wireless access service. In the ALL-IP network, a IP-based mobile communication network structure and protocol are used to perform IP-based transmission of data and signaling, to separate between transmission (bearer), control and service functions and to provide real-time multimedia communications.

The ALL-IP network is capable of providing services in cooperation with an Internet network irrespective of existing wired telephones, mobile telephones, cables or LANs by using IP, thereby obtaining a synergistic effect through IP expansion and reducing costs in providing the service.

The ALL-IP network also provides a solution suitable for an integrated service, which is an integrated multimedia service including all of voice, data and real-time video services. The ALL-IP network may be incorporated using IP and provides advantages of low operation and maintenance costs and cost reduction through packet transmission.

That is, the ALL-IP network is an IP-based integrated network for supporting a wired or wireless voice service, a wired or wireless Internet service, and a wired or wireless multimedia service.

An IP multimedia core network subsystem (IMS) is defined to provide a variety of services to subscribers based on the ALL-IP network.

The IMS is defined in 3GPP that in turn defines group special mobile (GSM), wideband code division multiple access (WCDMA) and the like, and similarly defined as a multimedia domain (MMD) in the 3rd generation partnership project 2 (3GPP2) that in turn defines code division multiple access (CDMA) and the like.

Although an IMS 100 will now be illustrated by way of example, it will be appreciated that the same applies to MMD.

FIG. 1 is an overall block diagram illustrating a network connection structure of a typical IP multimedia core network subsystem (IMS) network.

Referring to FIG. 1, the network includes a terminal 1 that allows a subscriber to receive an integrated service, a base station system 2 having a wireless connection to the terminal 1, a packet data service node (PDSN) 3 having a connection to the base station system 2 via a cable, and an IMS 100 having a connection to the PDSN 3 over an IP network.

The terminal 1 provides an integrated service, including a wired or wireless voice service, a wired or wireless Internet service and a wired or wireless multimedia service, to a subscriber.

That is, the terminal 1 receives a signal from the base station system 2 within a service cell of the base station system 2, and wirelessly transmits a signal to the base station system 2 in response to voice or data from the subscriber.

The base station system 2 transmits the signal from the terminal 1 within its service cell to the PDSN 3, which is connected to the base station system 2 over the wired network, and wirelessly transmits a signal from the PDSN 3 to the terminal 1 within the service cell.

That is, the base station system 2 assigns a radio channel to the terminal 1 within the service cell or releases the radio channel, and performs hand-off processing to guarantee the mobility of the terminal 1.

The base station system 2 translates an analog signal received from the terminal 1 within the service cell into a digital signal to transmit the digital signal to the PDSN 3 connected to the base station system 2 via an E1/T1 line over the wired network, and translates a digital signal from the PDSN 3 into an analog signal to wirelessly transmit the analog signal to the terminal 1.

Further, the PDSN 3 translates the received signal from the base station system 2 into an IP packet for transmission to the IMS 100, and translates an IP packet from the IMS 100 into a signal for transmission to the PDSN 3.

The network including the terminal 1, the base station system 2 and the PDSN 3 is called an access network. The terminal 1 transmits a message, based on a session initiation protocol (SIP) of a voice over Internet protocol (VoIP), to the IMS 100 over the access network.

That is, the terminal 1 wirelessly transmits the SIP message signal to the base station system 2 in response to a subscriber's request, and the base station system 2 transmits the received signal to the PDSN 3.

The PDSN 3 translates the received signal from the base station system 2 into an IP packet corresponding to an SIP message for transmission to the IMS 100.

The IMS 100 provides an integrated service to the terminal 1 in response to the received IP packet.

FIG. 2 is an internal block diagram of a typical IMS. Referring to FIG. 2, the IMS 100 includes a number of call session control function (CSCF) servers, for instance, a proxy-call session control function (P-CSCF) server 110, an interrogating-call session control function (I-CSCF) server 120 and a serving-call session control function (S-CSCF) server 130, and a home subscriber server (HSS) 140.

The P-CSCF server 110 transmits a received SIP message from the terminal 1 to the I-CSCF server 120.

The I-CSCF server 120 obtains subscriber information (profile) of the terminal 1 from public user ID information of the terminal 1, which transmitted the SIP message.

The I-CSCF server 120 also controls a call for the terminal 1 according to the obtained subscriber information and transmits a message to the S-CSCF server 130 providing the integrated service.

The S-CSCF server 130 provides the integrated service to the terminal 1 according to the received message. That is, the S-CSCF server 130 establishes calls for the called terminal 1 and the calling terminal 1 according to the received message, or provides the integrated service, such as a voice message service and the like.

The HSS 140 manages subscriber information according to each terminal 1 accessing the IMS 100, and upon receipt of a request for subscriber information of each terminal 1 from the I-CSCF server 120, provides the subscriber information corresponding to the public user ID information of the terminal 1 to the I-CSCF server 120.

As the number of subscribers accessing the IMS 100 increases, the number of HSSs 140 managing the subscriber information increases.

FIG. 3 is an internal block diagram of an IMS including a number of typical HSSs. As shown in FIG. 3, when the number of the subscriber terminals 1 accessing the IMS 100 increases, a number of HSSs 140-1 to 140-n distribute and manage the subscriber information (profile) according to the public user ID information of the terminals 1.

This needs an additional subscription locator function (SLF) server 150 capable of providing information about the respective HSSs 140-1 to 140-n which manage the subscriber information according to the public user ID information of the terminal 1 accessing the IMS 100.

That is, the SLF server 150 manages unique information of HSSs 140-1 to 140-n, which manage the subscriber information according to the public user ID information of the terminal 1 transmitting the message, and provides the unique information of the HSSs 140-1 to 140-n when the I-CSCF server 120 requests the unique information of HSSs 140-1 to 140-n corresponding to the public user ID information of the terminal 1.

The I-CSCF server 120 obtains the subscriber information of the terminal 1 from the corresponding HSSs 140-1 to 140-n according to the unique information of HSSs 140-1 to 140-n from the SLF server 150.

The SLF server 150, however, has not been implemented in the IMS 100.

That is, the unique information of the terminal 1 accessing the IMS 100 may be assigned a number of public user IDs. The public user ID may be of a session initiation protocol-uniform resource locator (SIP-URL) or a telephone-uniform resource locator (TEL-URL) type.

Accordingly, in the SLF server 150, as the number of terminals 1 accessing the IMS 100 increases, amount of information to be managed increases according to a geometric series, thereby requiring a large-scale database.

Further, since a key value used as the index in the SLF server 150 may be the SIP-URL or the TEL-URL that is a different type of public user ID information, a method of efficiently managing the public user ID information of the terminal 1 is required.

### SUMMARY OF THE INVENTION

Accordingly, the present invention has been made to solve the aforementioned problems. It is an object of the present invention to provide an apparatus and method for managing information in an integrated service providing system, which is capable of efficiently managing public user ID information of respective terminals accessing the IMS, implementing an SLF function with more stability in obtaining subscriber information for each terminal in the IMS in which a number of HSSs are built, and optimizing the SLF function in the IMS.

According to an embodiment of the present invention, there is provided an apparatus for managing information in a system providing an integrated service in an ALL-IP network, comprising at least a first server for managing subscriber information (profile) corresponding to ID information of at least one terminal accessing the system, a second server for transmitting a domain name server (DNS) inquiry message to request unique information from the first server, which manages the subscriber information corresponding to the ID information of the terminal, in response to receiving a service request message from each terminal; and a third server for storing unique information of each of the first servers, which manages the ID information of each terminal, retrieving the unique information from the first server corresponding to the ID information of the terminal included in the DNS inquiry message in response to receiving the DNS inquiry message from the second server, and transmitting a DNS response message including the retrieved unique information from the first server to the second server.

According to another embodiment of the present invention, there is provided an apparatus for managing information in a system providing an integrated service in an ALL-IP network, comprising at least one home subscriber server (HSS) for managing subscriber information (profile) corresponding to ID information of at least one terminal accessing the system; a call session control function (CSCF) for generating an inquiry message requesting unique information from the HSS corresponding to the ID information of each terminal in response to receiving a service request message from the at least one terminal, and obtaining subscriber information from the HSS based on a received response message; a subscription locator function (SLF) for translating the inquiry message to a domain name server (DNS) inquiry message for transmission in response to receiving the inquiry message generated by the CSCF, and translating a received DNS response message to a response message for transmission to the CSCF; and a domain name server (DNS) for managing the unique information of the respective HSSs, retrieving the unique information of the HSS corresponding to the ID information of each terminal in response to receiving the inquiry message from the SLF, and transmitting a DNS response message including the retrieved unique information to the SLF.

According to still another embodiment of the present invention, there is provided an apparatus for managing unique information of a server that manages information corresponding to IDs of terminals, the apparatus comprising a storage unit for storing unique information of a server that manages subscriber information corresponding to the ID information of each terminal connected over a network; a receiver for receiving a domain name server (DNS) inquiry message including the ID information of the terminal; a retrieving unit for retrieving unique information of the server corresponding to the ID of the terminal; and a transmitter for transmitting a DNS response message including the retrieved unique information.

According to yet another embodiment of the present invention, there is provided an apparatus for managing unique information corresponding to an ID of a terminal, the apparatus comprising a first receiver for receiving a service request message from the terminal; a transmitter for transmitting a domain name server (DNS) inquiry message including the ID information of the terminal to a server which manages unique information of a subscriber information management server; and a second receiver for receiving subscriber information of the terminal from the subscriber information management server corresponding to unique information of the subscriber information management server included in a DNS response message received from the server.

According to yet another embodiment of the present invention, there is provided a method for managing information in an integrated service providing system comprising at least a first server that manages subscriber information corresponding to ID information of respective terminals on an ALL-IP network; a second server that receives a message from each terminal; and a third server that translates domain address information to IP address information, the method comprising the steps of setting, in the third server, unique information of the first server that manages subscriber information (profile) corresponding to the ID information of the respective terminals; transmitting, by the second server, a domain name server (DNS) inquiry message to the third server requesting unique information of the first server corresponding to the ID information of the terminal in response to receiving a service request message from each terminal; retrieving, by the third server, the unique information of the first server corresponding to the ID information of the terminal included in the DNS inquiry message received from the second server, and transmitting a DNS response message including the retrieved unique information to the second server; and obtaining, by the second server, subscriber information from the first server using the unique information included in the DNS response message received from the third server.

According to yet another embodiment of the present invention, there is provided a method for managing information in an integrated service providing system comprising at least one home subscriber server (HSS) that manages subscriber information in an ALL-IP network; a call session control function (CSCF) that receives a request message from at least one terminal; a subscription locator function (SLF) that transmits an inquiry message in response to a request for unique information of the HSS from the CSCF; and a domain name server (DNS) that translates domain address information to IP address information, the method comprising the steps of setting, by the DNS, unique information of the HSS that manages subscriber information corresponding to ID information of each terminal; transmitting, by the CSCF, an inquiry message to the SLF according to a diameter protocol requesting the unique information of the HSS that manages subscriber information corresponding to the ID information of each terminal in response to receiving an SIP message from each terminal; translating, by the SLF, the received inquiry message to a DNS inquiry message and transmitting the DNS inquiry message to the DNS; retrieving, by the DNS, the unique information of the HSS that manages subscriber information corresponding to the ID information included in the received DNS inquiry message and transmitting a DNS response message to the SLF; transmitting, by the SLF, a response message including the unique information in the received DNS response message to the CSCF; and obtaining, by the CSCF, subscriber information from the HSS according to the unique information included in the received response message.

According to yet another embodiment of the present invention, there is provided a method for managing unique information of a server that manages information corresponding to IDs of terminals, the method comprising the steps of storing the unique information of the server that manages subscriber information corresponding to the ID information of each terminal connected over a network; receiving a domain name server (DNS) inquiry message including the ID information of the terminal from a service providing server; retrieving the unique information of the server that manages the subscriber information corresponding to the ID of the terminal; and transmitting a DNS response message including the unique information of the server that manages the subscriber information to the service providing server.

According to yet another embodiment of the present invention, there is provided a method for managing unique information corresponding to ID of a terminal, the method comprising the steps of receiving a service request message from the terminal; transmitting a domain name server (DNS) inquiry message including the ID information of the terminal to a server that manages the unique information of a subscriber information management server; receiving, from the server, a DNS response message that includes the unique information of the subscriber information management server corresponding to the ID of the terminal; and obtaining the subscriber information of the terminal from the subscriber information management server according to the received unique information of the subscriber information management server.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 is an overall block diagram illustrating a network connection structure of a typical IP multimedia core network subsystem (IMS) network;

FIG. 2 is an internal block diagram of a typical IMS;

FIG. 3 is an internal block diagram of an IMS including a number of typical home subscriber servers (HSSs);

FIG. 4 is an internal block diagram of an IMS according to an embodiment of the present invention;

FIG. 5 is a block diagram of devices for performing a subscription locator function (SLF) function in an IMS according to an embodiment of the present invention;

FIG. 6 is a conceptual diagram illustrating a case where a domain name server (DNS) stores unique information according to an embodiment of the present invention;

FIG. 7 is a flow diagram illustrating message exchange according to an embodiment of the present invention;

FIG. 8 is a flowchart illustrating a method for managing information in an IMS according to an embodiment of the present invention;

FIG. 9 is a block diagram of devices for performing an SLF function in an IMS according to an embodiment of the present invention;

FIG. 10 is a flow diagram illustrating message exchange according to an embodiment of the present invention;

FIG. 11 is a flowchart illustrating a method for managing information in an DNS according to an embodiment of the present invention; and

FIG. 12 is a flowchart illustrating a method for managing information in an IMS according to another embodiment of the present invention.

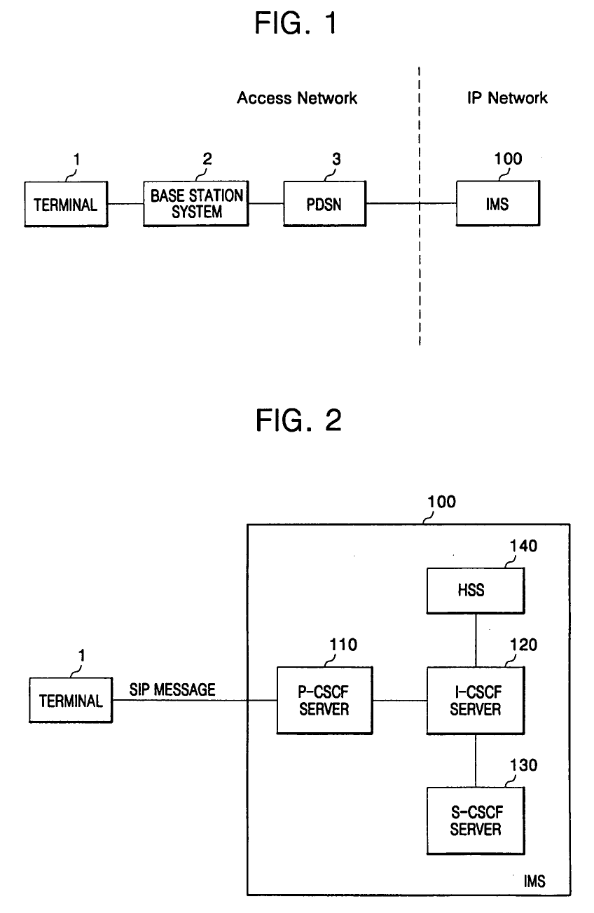

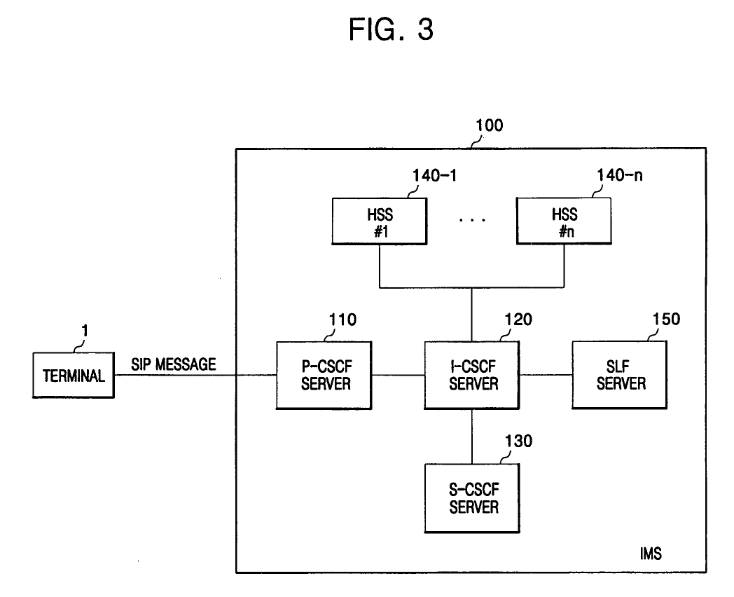

### DETAILED DESCRIPTION OF EXEMPLARY EMBODIMENTS

Hereinafter, an apparatus and method for managing information in an integrated service providing system according to exemplary embodiments of the present invention will be described in detail with reference to the accompanying drawings.

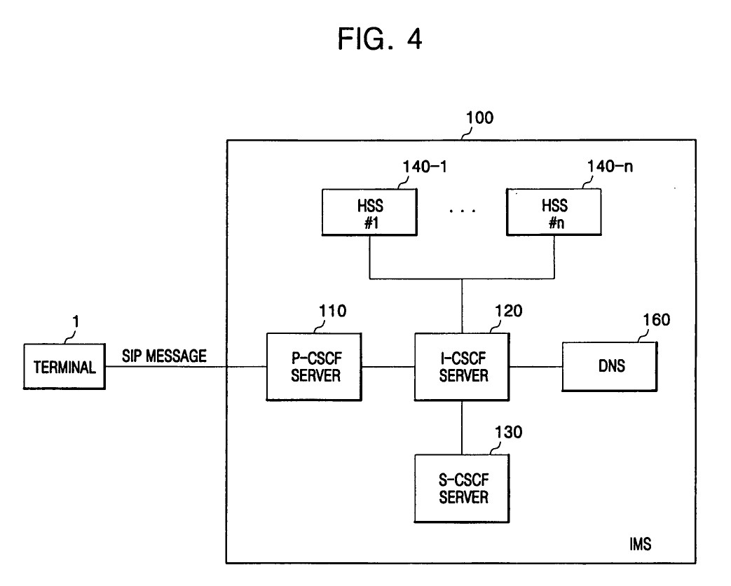

FIG. 4 is an internal block diagram of an IMS according to an embodiment of the present invention.

Referring to FIG. 4, an IMS 100′ according to an embodiment of the present invention preferably comprises a P-CSCF server 110, an I-CSCF server 120, an S-CSCF server 130, a DNS 160, and a number of HSSs 140-1 to 140-n.

The P-CSCF server 110 transmits an SIP message from the terminal 1 to the I-CSCF server 120.

The I-CSCF server 120 transmits the message to the S-CSCF server 130, which controls a call for the terminal 1 according to the subscriber information (profile) corresponding to the public user ID information that is the unique information of the terminal 1 in the received message.

The I-CSCF server 120 generates and transmits an inquiry message to the DNS 160 to confirm unique information of the HSS 140 which manages the subscriber information according to the public user ID information of the terminal 1.

The I-CSCF server 120 obtains subscriber information corresponding to the public user ID information of the terminal 1 from the HSS 140 according to the unique information of the HSS 140 in a response message received from DNS 160.

The DNS 160 retrieves unique information of the HSS 140 which manages the subscriber information according to the public user ID information in the inquiry message received from the I-CSCF server 120, and transmits a response message to the I-CSCF server 120, which includes the retrieved unique information of the HSS 140.

That is, the DNS 160 stores the unique information of the HSS 140 managing the subscriber information according to the public user ID information of each terminal 1 accessing the IMS 100, and retrieves the unique information of the HSS 140 according to the public user ID information in the inquiry message received from the I-CSCF server 120.

The DNS 160 transmits a response message including the retrieved unique information of the HSS 140 to the I-CSCF server 120.

The unique information of the HSS 140 included in the response message transmitted by the DNS 160 may be IP address information of the HSS 140.

The I-CSCF server 120 obtains the subscriber information of the terminal 1 from the HSS 140 by using the unique information included in the response message received from DNS 160.

The I-CSCF server 120 transmits a message to the S-CSCF server 130 to control the call of the terminal 1 according to the subscriber information obtained from the HSS 140, and the S-CSCF server 130 controls the terminal 1 call according to the received message and provides an integrated service.

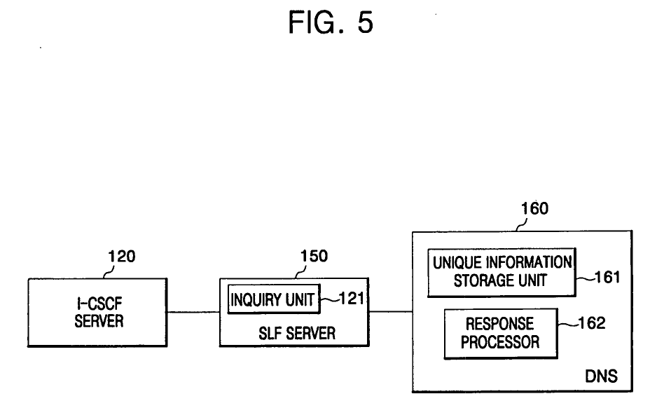

FIG. 5 is a block diagram of devices for performing an SLF function in an IMS according to an embodiment of the present invention.

A connection structure as shown in FIG. 5 includes an SLF server 150′ implemented in the IMS 100, in which unique information of the HSS 140 corresponding to the public user ID information is not stored in the SLF server 150′ as is presently implemented, and an optimized SLF function is implemented in the IMS 100″ by using the SLF server 150′ as a mere DNS 160 client.

In this case, the I-CSCF server 120 and the SLF server 150′ exchange the inquiry message and the response message according to the diameter protocol.

Here, the diameter protocol is described in detail in an article entitled “Diameter Base Protocol”, which was written by P. Calhoun et al. of the Network Working Group in response to the RFC request for comments 3588, pages 1-147, the entire text of which is hereby incorporated by reference. The protocol may be applied to the message exchange between the SLF server 150′ and the I-CSCF server 120 in the IMS 100″.

The SLF server 150′ includes an inquiry unit 121 functioning as the DNS 160 client. The DNS 160 comprises a response processor 162 for processing the inquiry message from the SLF server 150 and transmitting a response message, and a storage unit 161 for storing unique information of the HSS 140 corresponding to the public user ID information that is the unique information of the terminal 1 accessing the IMS 100″.

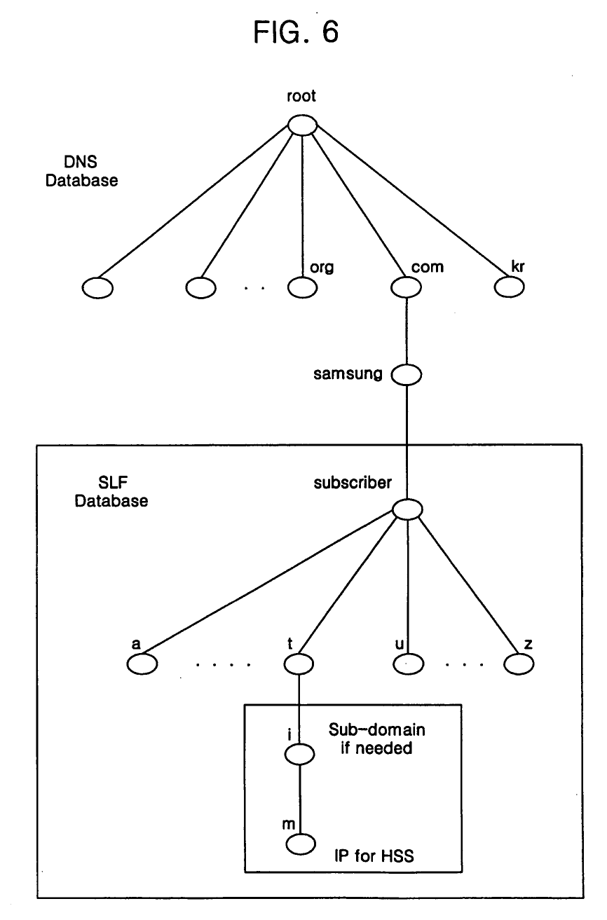

FIG. 6 is a conceptual diagram illustrating a case where a DNS server stores unique information according to an embodiment of the present invention.

As shown in FIG. 6, the IP address information, which is unique information of the HSS 140 corresponding to the public user ID information as the unique information of respective terminals 1, is stored in the unique information storage unit 161 of the DNS 160.

When the public user ID information of each terminal 1 is SIP-URL, the information may be stored in the unique information storage unit 161 to have a sub-layer structure in which sequential retrieval is allowed from an upper-level category to a lower-level category, as shown in FIG. 6.

That is, the unique information storage unit 161 in the DNS 160 may comprise a DNS database that stores domain information needed to cooperate with another IMS, and an SLF database that stores the unique information of the HSS 140.

Further, the unique information storage unit 161 stores IP address information or domain address information corresponding to a telephone number information in which the public user ID information of the respective terminal 1 is in the form of a TEL-URL.

That is, when the telephone number information in the form of a TEL-URL is included in the received inquiry message, the DNS 160 retrieves the IP address information or domain address information corresponding to the telephone number information and the unique information of the HSS 140 corresponding to the public user ID information of the terminal 1 and transmits the response message.

As shown in FIG. 6, for example, when the SIP message is received from the terminal 1 assigned the public user ID information in the form of SIP-URL of ‘mit@samsung.com’, for example, the I-CSCF server 120 transmits an inquiry message to the DNS 160 to retrieve the unique information of HSS 140 based on the public user ID information of the terminal 1.

The response processor 162 in the DNS 160 retrieves from the unique information storage unit 161 the unique information of the HSS 140 corresponding to the public user ID information of the terminal 1 included in the received inquiry message.

That is, the response processor 162 selects a route from ‘com’ to ‘samsung’ from the DNS 160 database that is an upper-level category, and a route from ‘t’ to ‘i’ to ‘m’ from the SLF database that is a lower-level category.

The response processor 162 generates a response message including the IP address information as the unique information of the HSS 140 stored in the lowest level of the selected route and transmits the response message to the I-CSCF server 120.

The I-CSCF server 120 may obtain subscriber information of the terminal 1 from the HSS 140 based on the IP address information included in the received response message.

The I-CSCF server 120 also obtains the subscriber information from the HSS 140 and transmits a message to the S-CSCF server 130, which provides an integrated service to the terminal 1. The S-CSCF server 130 controls the call for the terminal 1 to provide the integrated service.

That is, the DNS 160 may assign an area in a ‘subscriber.samsung.com’ zone to store the unique information of the HSS 140, and manage, as a domain, subscriber information of the respective terminals 1 for each subscriber on a per-character basis or through a bundle since the ‘mit’ positioned before the public user ID information such as ‘mit@samsung.com’ indicates a subscriber.

The DNS 160 retrieves the IP address information of HSS 140 to transmit a response message, which manages the subscriber information corresponding to the public user ID information of the terminal 1, which is included in the inquiry message from the inquiry unit 121 that is the DNS 160 client.

Such a unique information storage structure of the unique information storage unit 161 does not affect a function of the DNS 160 for cooperation with another IMS 100″ as shown in FIG. 5 by adding an SLF database that stores the IP address information of the HSS 140 in the form of a sub-domain to the domain management structure of the DNS 160 for the cooperation with another existing IMS 100″.

That is, when the terminal 1 accessing the IMS 100″ requests an integrated service with the terminal 1 accessing another IMS 100″, the DNS 160 client requests the DNS 160 to provide the domain address information of another IMS 100″, and the DNS 160 does not retrieve the IP address information of the HSS 140 stored as the sub-domain but retrieves domain address information of another IMS 100″ from the DNS 160 database to transmit the response message.

When a number of the terminal 1 subscribers accessing the IMS 100″ increases, the manager of the DNS 160 may distinguish between the subscribers using a proper number of sub-domains, and the IP address information of the HSS 140 included in the respective sub-domains may be configured as domain address information that only servers managing the upper-level category are allowed to access.

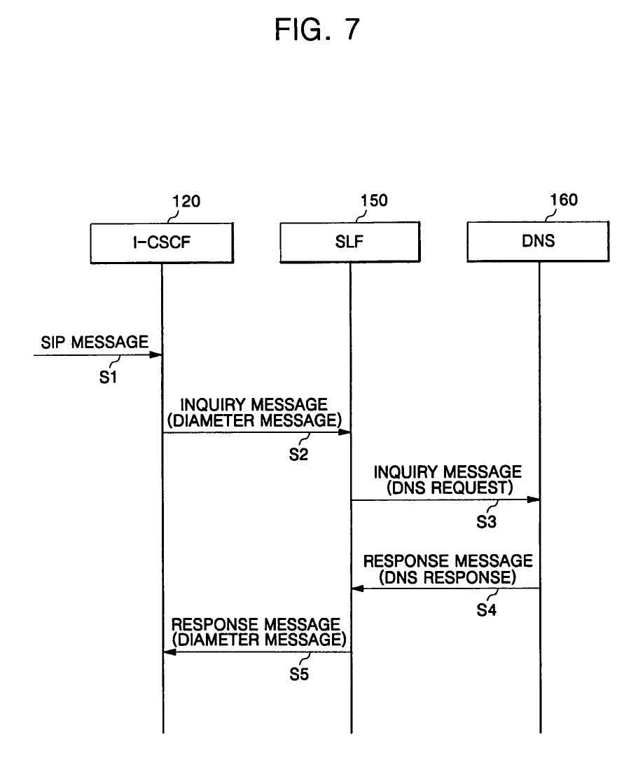

FIG. 7 is a flow diagram illustrating message exchange according to an embodiment of the present invention.

Referring to FIG. 7, when the I-CSCF server 120 receives the SIP message from the terminal 1 (S1), it transmits an inquiry message to the SLF server 150′ according to the diameter protocol to inquire IP address information that is unique information of the HSS 140, which manages the subscriber information of the terminal 1 transmitting the message (S2).

The SIP message transmitted by the terminal 1 may be an integrated service request message, such as an ‘INVITE’ message, an ‘REGISTER’ message or the like.

When the inquiry unit 121 of the SLF server 150′ receives the inquiry message from the I-CSCF server 120, it transmits an inquiry message to the DNS 160, which manages the IP address information that is the unique information of the HSS 140 (S3).

The inquiry message that the inquiry unit 121 transmits to the DNS 160 may be a message of ‘A’ or ‘naming authority pointer (NAPTR)’ type requesting address information used in the DNS 160, and includes the public user ID information of the terminal 1 transmitting the SIP message.

When the response processor 162 in the DNS 160 receives the inquiry message from the inquiry unit 121 of the SLF server 150, it retrieves the IP address information that is unique information of the HSS 140, which manages the subscriber information of the terminal 1, from the SLF database in the unique information storage unit 161.

The response processor 162 transmits a response message to the SLF server 150 which includes the IP address information of the HSS 140 retrieved from the storage unit (S4).

The SLF server 150′ recognizes the IP address information of the HSS 140 from the received response message.

The SLF server 150′ also transmits a response message including the recognized IP address information of the HSS 140 to the I-CSCF server 120 according to the diameter protocol (S5).

Further, the I-CSCF server 120 obtains the subscriber information of the terminal 1 transmitting the SIP message by gaining an access to the HSS 140 using the IP address information included in the received response message.

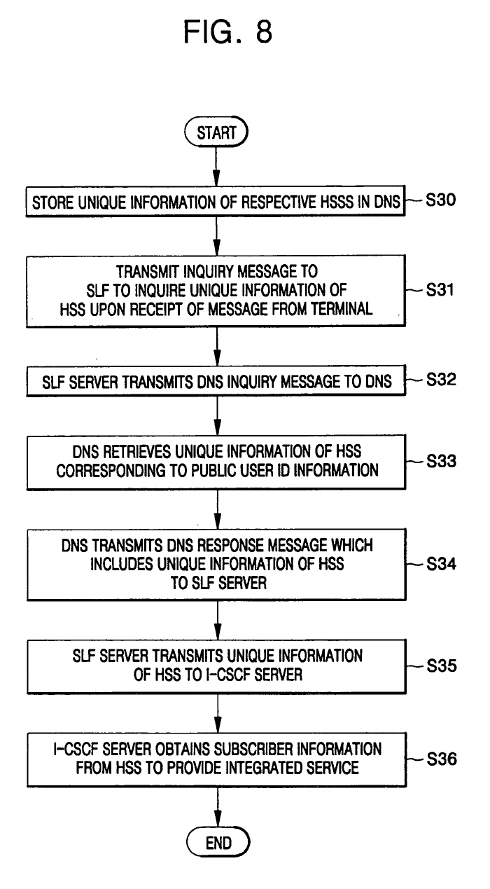

FIG. 8 is a flowchart illustrating a method for managing information in an IMS according to an embodiment of the present invention.

Referring to FIG. 8, SLF information, such as unique information of the HSS 140 managing the subscriber information of the terminal 1, is stored in the DNS 160 (S30).

When the IMS 100″ receives an SIP message from the terminal 1, the I-CSCF 120 transmits an inquiry message including the public user ID information of the terminal 1 to the SLF 150′ according to the diameter protocol (S31).

Here, the SIP message transmitted by the terminal 1 may be the integrated service request message, such as an ‘INVITE’ message, a ‘REGISTER’ message or the like.

Upon receipt of the inquiry message from the I-CSCF server 120, the inquiry unit 121 in the SLF server 150′ transmits the inquiry message to the DNS 160, which manages the IP address information that is the unique information of the HSS 140 (S32).

The inquiry message that the inquiry unit 121 transmits to the DNS 160 may be of an ‘A’ or ‘naming authority pointer (NAPTR)’ type requesting address information used in the DNS 160, and includes the public user ID information of the terminal 1 transmitting the SIP message.

When the response processor 162 in the DNS 160 receives the inquiry message from the inquiry unit 121 of the SLF server 150′, it retrieves IP address information that is unique information of the HSS 140, which manages the subscriber information of the terminal 1, from the SLF database in the unique information storage unit 161 (S33).

The response processor 162 transmits a DNS response message to the SLF server 150′ which includes the IP address information of HSS 140 retrieved from the storage unit (S34).

The SLF server 150′ recognizes the IP address information of HSS 140 in the received response message.

The SLF server 150′ also transmits a response message including the recognized IP address information of HSS 140 to the I-CSCF server 120 according to the diameter protocol (S35).

Further, the I-CSCF server 120 gains access to the HSS 140 using the IP address information included in the received response message, obtains the subscriber information of the terminal 1 transmitting the SIP message, and provides the integrated service (S36).

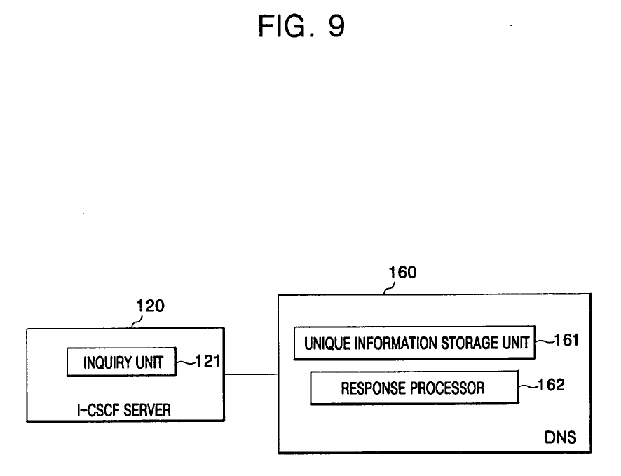

FIG. 9 is a block diagram of devices for performing an SLF function in an IMS according to another embodiment of the present invention.

FIG. 9 illustrates the I-CSCF server 120′ including an inquiry unit 121 that is a DNS 160 client, in which a manager constituting the IMS 100′″ implements the DNS 160 client in the I-CSCF server 120′.

As shown in FIG. 9, the I-CSCF server 120′ includes the inquiry unit 121 that is the DNS 160 client, and the DNS 160 includes a response processor 162 for processing a received inquiry message, and a unique information storage unit 161 for storing unique information of the HSS 140, which manages subscriber information corresponding to the public user ID information of a terminal 1 accessing the IMS 100′″.

The information stored in the unique information storage unit 161 has a structure as illustrated in FIG. 6 and may store IP address information that is unique information of the HSS 140.

Further, the unique information storage unit 161 stores IP address information or domain address information corresponding to a TEL-URL type of telephone number information of the terminal 1 accessing the IMS 100, and unique information of the HSS 140 corresponding to the public user ID information of the terminal 1.

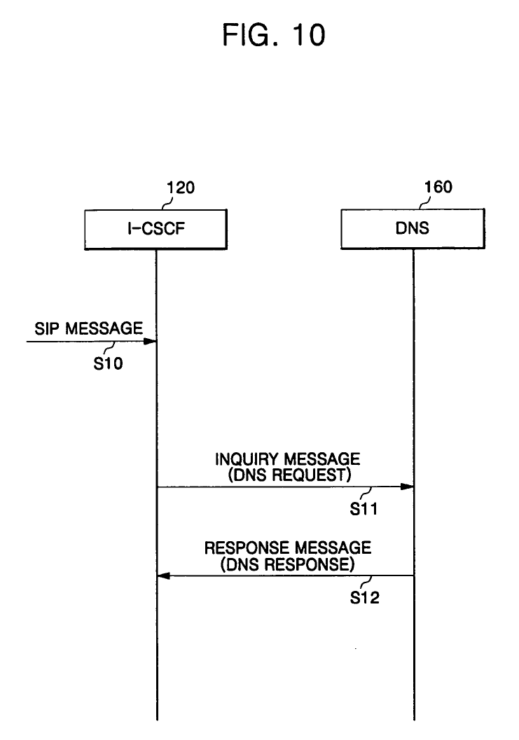

FIG. 10 is a flow diagram illustrating message exchange according to another embodiment of the present invention.

As shown in FIG. 10, when the I-CSCF server 120′ receives an SIP message from the terminal 1 (S10), the inquiry unit 121 of the I-CSCF server 120′ transmits an inquiry message to the DNS 160 (S11).

The inquiry message that the inquiry unit 121 transmits to the DNS 160 may be a message of an ‘A’ or ‘naming authority pointer (NAPTR)’ type used in the DNS 160, and includes the public user ID information of the terminal 1 transmitting the SIP message.

When the response processor 162 in the DNS 160 receives the inquiry message from the I-CSCF server 120′, it retrieves the IP address information that is the unique information of the HSS 140, which manages the subscriber information of the terminal 1, from the SLF database of the unique information storage unit 161.

The response processor 162 transmits a response message to the I-CSCF server 120′ that preferably includes the IP address information of the HSS 140 retrieved from the unique information storage unit 161 (S12).

Further, the I-CSCF server 120′ gains access to the HSS 140 using the IP address information included in the received response message and obtains the subscriber information of the terminal 1.

Meanwhile, when the inquiry unit 121, which is the DNS 160 client, transmits the inquiry message including the public user ID information in response to the message received from the terminal 1, it is required to translate the public user ID information so that the DNS 160 retrieves the unique information of the HSS 140 based on the inquiry message.

Although in the following example where the inquiry unit 121, which is the DNS 160 client, transmits an NAPTR type of inquiry message will be now described, the same may apply to other defined types of inquiry message.

The public user ID information used in the IMS 100′″ may be either a TEL-URL or a SIP-URL. A case will be first described where the public user ID information is TEL-URL.

When the public user ID information of the terminal 1 transmitting the SIP message is ‘+119’ that is the TEL-URL, the inquiry unit 121 translates the public user ID information and transmits the inquiry message including the public user ID information requesting the unique information of the HSS 140, which manages the subscriber information of the terminal 1.

Since the unique information storage unit 161 of the DNS 160 stores an NAPTR type of information, the response processor 162 transmits to the DNS 160 client the response message that includes the unique information of the HSS 140 managing the subscriber information for ‘+119’.

For example, the NAPTR type of information stored in the unique information storage unit 161 of the DNS 160 may be in the form of, for example, ‘9.1.1 IN NAPTR 65000 0 “u” “SLF+E2U” “!ˆ.*$!HSS 140 5.samsung.com!”’ or ‘9.1.1 IN NAPTR 65000 0 “u” “SLF+E2I” “!ˆ.*$!10.155.1.14!”’.

The ‘9.1.1’ indicates ENUM (Telephone Number Mapping or E.164 Number Mapping) translation of ‘+119’ that is TEL-URL of the terminal 1 transmitting the SIP message, and “SLF+E2U” or “SLF+E2I” indicates that the response message to the inquiry message is for the SLF function.

The “!ˆ.*$!HSS 140 5.samsung.com!” or ‘!ˆ.*$!10.155.1.14!” specifies the HSS 140 managing the subscriber information of the terminal 1.

Further, the DNS 160 client recognizes the unique information of the HSS 140 from “SLF+E2U” or “SLF+E2I” included in the received response message and obtains the subscriber information from the HSS 140.

The inquiry unit 121 translates the public user ID information to be in the form of ‘m.i.t.subscriber.samsung.com’ and then transmits the inquiry message to the DNS 160 when the public user ID information of the terminal 1 transmitting the SIP message is ‘mit@samsung.com’ that is SIP-URL.

Here, the ‘subscriber’ specifies sub-domain information stored in the SLF database of the unique information storage unit 161 and becomes sub-layer structure information.

The response processor 162 in the DNS 160 retrieves the unique information of the HSS 140 based on the SIP-URL included in the inquiry message, and transmits a response message to the DNS 160 client that includes the unique information of the HSS 140.

In this case, the response message transmitted by the DNS 160 may include information such as ‘m.i.t A 10.155.1.14.’ The unique information of the HSS 140, which manages the subscriber information of the terminal 1 assigned the ‘mit’ address information, specifies ‘10.155.1.14.’

The ‘A’ specifies that the response message is of an ‘A’ type since the inquiry message transmitted by the DNS 160 client is of the ‘A’ type.

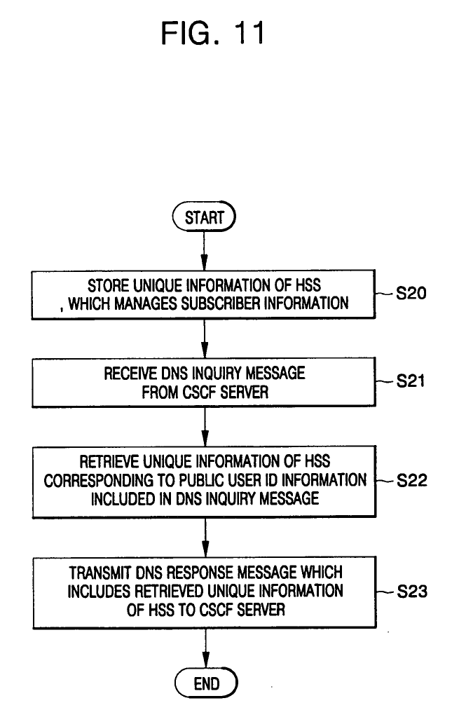

FIG. 11 is a flowchart illustrating a method for managing information in an DNS according to another embodiment of the present invention.

Referring to FIG. 11, a manager of the IMS 100″ stores the unique information of the HSS 140, which manages SLF information, such as subscriber information of the terminal 1 accessing the IMS 100, in the unique information storage unit 161 of the DNS 160 in the structure such as in FIG. 6 (S20).

When the response processor 162 of the DNS 160 receives the inquiry message including the public user ID information of the terminal 1 from the I-CSCF server 120 (S21), it retrieves the unique information of the HSS 140 corresponding to the public user ID information from the unique information storage unit 161 (S22).

The received inquiry message from the I-CSCF server 120 may be of an ‘A’ or ‘NAPTR’ type, and the DNS 160 retrieve the unique information of the HSS 140, which manages the subscriber information corresponding to the included public user ID information based on the type of the received inquiry message.

The response processor 162 transmits to the I-CSCF server 120 a response message that includes the unique information of the HSS 140 retrieved from the unique information storage unit 161 (S23).

As such, the response processor 162 retrieves the unique information of the HSS 140 based on the type of the received inquiry message, and transmits the response message having the same type as that of the inquiry message to the I-CSCF server 120. The DNS 160 and the I-CSCF server 120 may exchange the message according to the diameter protocol.

The I-CSCF server 120 also obtains the subscriber information from the HSS 140 based on the unique information of the HSS 140 included in the response message.

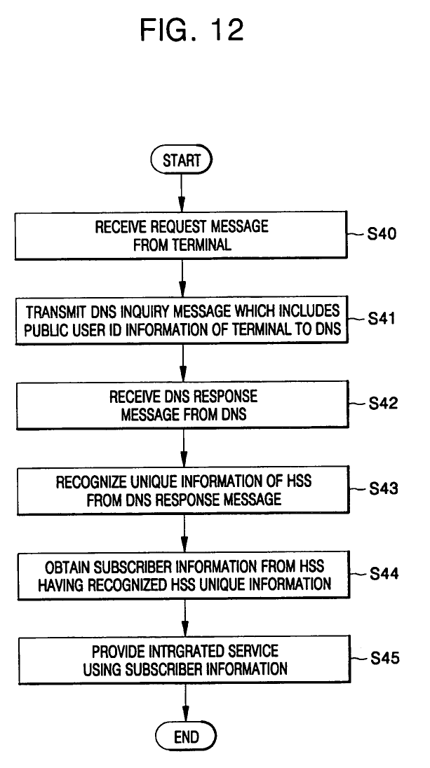

FIG. 12 is a flowchart illustrating a method for managing information in an IMS according to another embodiment of the present invention.

Referring to FIG. 12, a terminal 1 transmits an SIP message to an IMS 100′″ according to a subscriber's request, and the I-CSCF server 120′ receives the request message from the terminal 1 (S40).

The SIP message that the terminal 1 transmits to the IMS 100′″ may be an integrated service request message, such as an ‘INVITE’ message, an ‘REGISTER’ message or the like.

In response to receiving the message from the terminal 1, the I-CSCF server 120′ transmits an ‘A’ or ‘NAPTR’ type of DNS inquiry message to the DNS 160 which includes public user ID information of the terminal 1 (S41).

The DNS inquiry message transmitted by the I-CSCF server 120 is a message to inquire the unique information of the HSS 140, which manages the subscriber information of the terminal 1 transmitting the SIP message. The I-CSCF server 120′ translates the public user ID information of the terminal 1 for retrieval by the DNS 160 and includes the resultant information in the DNS inquiry message.

When the public user ID information of the terminal 1 is of an SIP-URL type, the inquiry unit 121 of the I-CSCF server 120′ translates the public user ID information so that the DNS 160 retrieves the unique information of the HSS 140 from the SLF database of the unique information storage unit 161.

The DNS 160 retrieves the unique information of the HSS 140, which manages the subscriber information of the terminal 1, from the unique information storage unit 161 based on the public user ID information in the received inquiry message from the I-CSCF server 120′ or, in an alternative embodiment not shown, the SLF server 150 that is a DNS client, and transmits the DNS response message including the retrieved unique information of the HSS 140 to the I-CSCF server 120′, which is the DNS 160 client.

That is, the I-CSCF server 120′ receives the DNS response message including the unique information of the HSS 140 from the DNS 160 after it transmits the DNS inquiry message (S42).

The I-CSCF server 120′ recognizes the unique information of the HSS 140 from the received response message (S43).

The I-CSCF server 120′ gains access to the HSS 140 using the unique information of the HSS 140 recognized from the received response message, and obtains from the HSS 140 the subscriber information of the terminal 1 transmitting the message (S44).

The I-CSC server 120′ also transmits the message to the S-CSCF server 130 according to the subscriber information obtained from the HSS 140, and the S-CSCF server 130 provides the integrated service to the terminal 1 according to the received message (S45).

Although the IMS suggested by the 3GPP has been illustrated by way of example, it will be appreciated that the same may also apply to the MMD suggested by the 3GPP2.

As described above, according to embodiments of the present invention, it is possible to efficiently manage public user ID information of terminals accessing the IMS and implement an SLF function with higher stability in obtaining subscriber information of the terminals by constructing a number of HSSs as the number of the terminals accessing the IMS increases.

It is also possible to implement an SLF function with stability without constructing a separate SLF server by constructing a database for performing an SLF function in a DNS, which is constructed in the IMS to cooperate with another IMS.

While the present invention has been described with reference to exemplary embodiments thereof, it will be understood by those skilled in the art that various changes in form and detail may be made therein without departing from the scope of the present invention as defined by the following claims.

What is claimed is:

1. An apparatus for managing information in a system providing an integrated service in an ALL-IP network, comprising:
at least a first server for managing subscriber information (profile) corresponding to ID information of at least one terminal;
a second server for transmitting a domain name server (DNS) inquiry message requesting unique information of the first server, which manages the subscriber information corresponding to the ID information of the terminal, in response to receiving a service request message from each terminal; and
a third server for storing unique information of each of a plurality of first servers, which manages the ID information of each terminal, retrieving the unique information of the first server corresponding to the ID information of the terminal included in the DNS inquiry message in response to receiving the DNS inquiry message from the second server, and transmitting a DNS response message including the retrieved unique information of the first server to the second server.

2. The apparatus according to claim 1, wherein the second server obtains subscriber information from the first server based on the unique information included in the DNS response message from the third server.

3. The apparatus according to claim 1, wherein the third server comprises:
a storage unit for storing unique information of each of a plurality of first servers, which manages the subscriber information corresponding to the ID information of each terminal; and
a response processor for retrieving, from the storage unit, the unique information of the first server corresponding to the ID information of the terminal in the DNS inquiry message received from the second server, and transmitting the DNS response message including the retrieved unique information to the second server.

4. The apparatus according to claim 1, wherein the ID information of the terminal is at least one of a session initiation protocol-uniform resource locator (SIP-URL) type of domain address information and a telephone-uniform resource locator (TEL-URL) type of number information.

5. The apparatus according to claim 1, wherein the second server includes an inquiry unit for generating an “A” or naming authority pointer (NAPTR) type of DNS inquiry message according to the ID information of the terminal included in the service request message.

6. The apparatus according to claim 1, wherein the second server stores the unique information of the first server corresponding to the ID information of each terminal in a sub-layer structure.

7. The apparatus according to claim 1, wherein the unique information of the first server is Internet protocol (IP) address information.

8. An apparatus for managing information in a system providing an integrated service in an ALL-IP network, comprising:
at least one home subscriber server (HSS) for managing subscriber information (profile) corresponding to ID information of at least one terminal;
a call session control function (CSCF) for generating an inquiry message requesting unique information of the HSS corresponding to the ID information of each terminal in response to receiving a service request message from the at least one terminal, and obtaining subscriber information from the HSS based on a received response message;
a subscription locator function (SLF) for translating the inquiry message to a domain name server (DNS) inquiry message for transmission in response to receiving the inquiry message generated by the CSCF, and translating a received DNS response message to a response message for transmission to the CSCF; and
a domain name server (DNS) for managing the unique information of the respective HSSs, retrieving the unique information of the HSS corresponding to the ID information of each terminal in response to receiving the inquiry message from the SLF, and transmitting a DNS response message including the retrieved unique information to the SLF.

9. The apparatus according to claim 8, wherein the SLF comprises an inquiry unit for translating the DNS inquiry message received from the CSCF according to a diameter protocol to the DNS inquiry message for transmission to the DNS according to a user datagram protocol (UDP).

10. An apparatus for managing unique information of a server that manages information corresponding to IDs of terminals, the apparatus comprising:
a storage unit for storing the unique information of a server that manages subscriber information corresponding to the ID information of each terminal connected over a network;
a receiver for receiving a domain name server (DNS) inquiry message including the ID information of the terminal;
a retrieving unit for retrieving the unique information of the server corresponding to the ID of the terminal; and
a transmitter for transmitting a DNS response message including the retrieved unique information.

11. An apparatus for managing unique information corresponding to ID of a terminal, the apparatus comprising:
a first receiver for receiving a service request message from the terminal;
a transmitter for transmitting a domain name server (DNS) inquiry message including the ID information of the terminal to a server which manages the unique information of a subscriber information management server; and
a second receiver for receiving subscriber information of the terminal from the subscriber information management server corresponding to the unique information of the subscriber information management server included in a DNS response message received from the server.

12. A method for managing information in an integrated service providing system comprising at least a first server that manages subscriber information corresponding to ID information of respective terminals on an ALL-IP network; a second server that receives a message from each terminal; and a third server that translates domain address information to IP address information, the method comprising the steps of:
setting, in the third server, unique information of the first server that manages the subscriber information (profile) corresponding to the ID information of the respective terminals;
transmitting, by the second server, a domain name server (DNS) inquiry message to the third server requesting unique information of the first server corresponding to the ID information of the terminal in response to receiving a service request message from each terminal;
retrieving, by the third server, the unique information of the first server corresponding to the ID information of the terminal included in the DNS inquiry message received from the second server, and transmitting a DNS response message including the retrieved unique information to the second server; and
obtaining, by the second server, subscriber information from the first server using the unique information included in the DNS response message received from the third server.

13. The method according to claim 12, wherein the DNS inquiry message is an “A” or naming authority pointer (NAPTR) type of DNS inquiry message corresponding to the ID information of the terminal included in the service request message.

14. The method according to claim 12, wherein the step of setting, in the third server, the unique information of the first server comprises a step of setting the unique information of the first server corresponding to the ID information of each terminal in a sub-layer structure.

15. A method for managing information in an integrated service providing system comprising at least one home subscriber server (HSS) that manages subscriber information in an ALL-IP network; a call session control function (CSCF) that receives a request message from at least one terminal; a subscription locator function (SLF) that transmits an inquiry message in response to a request for unique information of the HSS from the CSCF; and a domain name server (DNS) that translates domain address information to IP address information, the method comprising the steps of:
setting, by the DNS, unique information of the HSS that manages subscriber information corresponding to ID information of each terminal;
transmitting, by the CSCF, an inquiry message to the SLF according to a diameter protocol to inquire the unique information of the HSS that manages subscriber information corresponding to the ID information of each terminal in response to receiving an SIP message from each terminal;
translating, by the SLF, the received inquiry message to a DNS inquiry message and transmitting the DNS inquiry message to the DNS;
retrieving, by the DNS, the unique information of the HSS that manages subscriber information corresponding to the ID information included in the received DNS inquiry message and transmitting a DNS response message to the SLF;
transmitting, by the SLF, a response message including the unique information recognized from the received DNS response message to the CSCF; and
obtaining, by the CSCF, subscriber information from the HSS according to the unique information included in the received response message.

16. A method for managing unique information of a server that manages information corresponding to IDs of terminals, the method comprising the steps of:
storing the unique information of the server that manages subscriber information corresponding to the ID information of each terminal connected over a network;
receiving a domain name server (DNS) inquiry message including the ID information of the terminal from a service providing server;
retrieving the unique information of the server that manages the subscriber information corresponding to the ID of the terminal; and
transmitting a DNS response message including the unique information of the server that manages the subscriber information to the service providing server.

17. A method for managing unique information corresponding to ID of a terminal, the method comprising the steps of:
receiving a service request message from the terminal;
transmitting a domain name server (DNS) inquiry message including the ID information of the terminal to a server that manages the unique information of a subscriber information management server;
receiving, from the server, a DNS response message that includes the unique information of the subscriber information management server corresponding to the ID of the terminal; and
obtaining the subscriber information of the terminal from the subscriber information management server according to the received unique information of the subscriber information management server.
